(19) United States
(12) Patent Application Publication
(10) Pub. No.: US 2026/0227717 A1
(43) Pub. Date: Aug. 6, 2026

(54) Projection Exposure Apparatus for Semiconductor Lithography Comprising a Connecting Element

(71) Applicant: Carl Zeiss SMT GmbH, Oberkochen (DE)

(72) Inventors: Timo SPEIDEL, Ulm (DE); Carina KURTH, Stuttgart (DE); Johannes KRUIS, Oberkochen (DE)

(21) Appl. No.: 19/576,090

(22) Filed: Mar. 24, 2026

Related U.S. Application Data
(63) Continuation of application No. PCT/EP2024/075764, filed on Sep. 16, 2024.

(30) Foreign Application Priority Data
Sep. 27, 2023 (DE) 102023209476.2

(51) Int. Cl. G03F 7/00

(52) U.S. Cl. CPC G03F 7/70991; G03F 7/70216

(57) ABSTRACT

A projection exposure apparatus for semiconductor lithography comprises a connecting element for connecting two components of the projection exposure apparatus. The connecting element comprises a first mechanical decoupling element and a second decoupling element. The first mechanical decoupling element and the second decoupling element decouple the same sections of the connecting element from each other.

### CROSS-REFERENCE TO RELATED APPLICATIONS

The present application is a continuation of, and claims benefit under 35 USC 120 to, international application No. PCT/EP2024/075764, filed Sep. 16, 2024, which claims benefit under 35 USC 119 of German Application No. 10 2023 209 476.2, filed Sep. 27, 2023. The entire disclosure of each of these applications is incorporated by reference herein.

### FIELD

The disclosure relates to a projection exposure apparatus for semiconductor lithography having a connecting element.

### BACKGROUND

Energy, signals and fluids are typically exchanged between the components of a projection exposure apparatus of semiconductor technology using connecting elements. In this case, one of the components may be in the form of an optical element—for example a mirror in the projection exposure apparatus—which may optionally be positioned in at least three degrees of freedom for the purpose of optimizing the imaging quality. The connecting elements represent a mechanical connection between the components which can also transmit undesired mechanical vibrations. Therefore, the connecting elements are usually designed in such a way that only minimal static and dynamic forces can be transmitted from one component to a component connected thereto, i.e. the components are maximally decoupled from each other.

The static force depends in general on the static stiffness of the connecting element and the deflection of the two components relative to each other.

Like dynamic stiffness, the dynamic force is generally frequency-dependent, and it is determinable by the transmission properties of the connecting element at different frequencies, e.g. its natural frequency. The mass of the connecting element typically affects the transmission properties of the connecting element and hence the transmitted dynamic force at a specific frequency of a relative vibration of two components with respect to each other. The forces exerted on the connecting element over a frequency range thereby and the resultant movements usually have an influence on the controllability of a positioning component and may lead to unstable control.

Especially in the context of connecting elements for fluids, the response of the connecting elements to the internal pressure in the connecting element often plays an increasingly relevant role. In this context, the behavior in the case of a static operating pressure is considered, but also the transmission behavior in the case of dynamic pressure fluctuations in the fluid, i.e. mechanical vibrations transmitted by way of the fluid.

The internal pressure in the connecting element can lead to parasitic forces and moments at the connections to the adjacent components, referred to as pressure reaction loads below. These generally depend on the ratio of the angular stiffness to the axial stiffness of the connecting elements.

Some known metal bellows are formed as decoupling elements between the generally stiff tubular sections of the connecting element and have a relatively low axial stiffness. The axial and angular stiffnesses of the bellows are coupled; stiffening the bellows in the axial direction would also increase the angular stiffness. This could worsen the static and dynamic transmission properties of the connecting element.

### SUMMARY

The present disclosure seeks to provide an improved device.

In an aspect, the disclosure provides a projection exposure apparatus according to the disclosure for semiconductor lithography comprises at least one connecting element for connecting two components of the projection exposure apparatus. The connecting element comprises at least one first mechanical decoupling element and at least one second decoupling element. According to the disclosure, the first decoupling element and the second decoupling element decouple the same sections of the connecting element from each other. The decoupling elements are arrangeable between the two sections in such a way that their stiffnesses act in combination, i.e. the stiffnesses complement each other to form a jointly acting stiffness between the sections. Especially in the case of fluid-conducting connecting elements, it is possible as a result to influence not only the static and dynamic behavior of the connecting element itself but also the static and dynamic behavior of the connecting element caused by an internal pressure in the connecting element. The internal pressure is generated by a pressure difference between the interior and exterior of the connecting element, for which reason the term differential pressure is also used instead of the term internal pressure. In this case, the stiffnesses of the decoupling elements are designed such that the effects both of the static and dynamic behavior of the connecting element as a mechanical connection between the components and of the static and dynamic behavior due to a change in the internal pressure in the connecting element on at least one component are reduced or avoided entirely.

The first mechanical decoupling element may be a bellows. The second decoupling element may be in the form of a joint which is designed to be stiff in at least one predetermined direction. In this context, stiff is intended to mean that the stiffness of the decoupling element is designed to be as high as possible or as stiff as desired in the context of the design of the geometry and the technical characteristics of the material used, such as for example yield strengths or flexural strengths.

By contrast, flexible should be understood to mean the minimum possible or desired stiffness in the context of the design of the geometry and the technical properties of the material used. As a result, the ratio of angular stiffness to axial stiffness, for example, can be set in such a way that the effects of the static and dynamic behavior of the connecting element on the components can be reduced and/or avoided entirely. The ratio of angular stiffness to axial stiffness can be in a range from 1:20 to 1:1000 or more, for example. The ratio may have a significant influence on the effects of the static and dynamic properties of the connecting element in the event of a change in the internal pressure, wherein the static and dynamic transmission behavior of the connecting element itself need not be changed significantly as a result.

The predetermined stiff direction may correspond to the axial direction of the decoupling elements. This can lead to the reduction in the ratio of angular stiffness to axial stiffness in the decoupling elements as explained further above. In this case, the axially stiff decoupling element may have a monolithic form, wherein the monolithic structure may be produced both by way of conventional manufacturing methods, such as turning, milling, waterjet cutting and/or electrical discharge machining, and by way of additive manufacturing methods.

In an embodiment, at least one decoupling element is capable of decoupling the rotation about all directions perpendicular to the stiff direction. For example, this may be realized by way of a decoupling mechanism in two orthogonal degrees of rotational freedom perpendicular to the stiff direction, for example as formed in a universal joint. In this context, the joint axes of the two joints in the universal joint may intersect at a point which ideally also corresponds to the stiffness centers of the two decoupling elements. The universal joint may be produced by conventional manufacturing methods or, in an alternative, by an additive method as well.

In an embodiment, the first decoupling element and the second decoupling element may be arranged coaxially. A coaxial arrangement is based on the assumption of predominantly rotationally symmetric decoupling elements which have a common longitudinal axis. For example, a first decoupling element in the form of a bellows may be arranged coaxially with a universal joint of tubular design.

The first decoupling element and the second decoupling element may have a common center of stiffness. The center of stiffness corresponds by definition to the point through which the restoring forces of a system act (IS: 1893-2002) and is determined by the stiffnesses in the system. When considering the two decoupling elements as a system, it is desirable for the two decoupling elements to have a common center of stiffness, i.e. the same center of stiffness, whereby parasitic forces and moments on the sections are avoided. In the case of a pure rotation, the pivot point of the system, for example of a joint, may correspond to the center of stiffness of the system.

In an embodiment, at least one decoupling element may be designed to be fluid-tight. For example, the decoupling element may be in the form of a bellows, tube or sleeve. The bellows, which may be designed as metal bellows for example, can have a comparatively high rotational stiffness about the longitudinal axis of the bellows owing to its construction, with the other two orthogonal degrees of rotational freedom and the lateral stiffness being designed to be comparatively low. In combination with a universal joint arranged in parallel, the rotational stiffness of the bellows may be combined with the comparatively high axial stiffness of the universal joint, with frequently a lower rotational stiffness about the stiff axis. Thus, the decoupling elements connected in parallel jointly bring about a decoupling of the two sections decoupled by the decoupling elements, with the predetermined rotational stiffness being contributed by the bellows and the predetermined axial stiffness being contributed by the universal joint. The other angular stiffnesses for a predetermined decoupling mechanism may be designed to be comparatively soft both in the bellows and in the universal joint.

In the case of a tube or a sleeve, by contrast, the tube and the sleeve are in general merely capable of constituting a fluid-tight decoupling element of soft design in all degrees of freedom, whereas the second decoupling element connected in parallel has the predetermined comparatively high stiffness in at least one direction. In the case described further above, the second decoupling element may have high stiffnesses in the axial direction and in the rotation about the same.

The decoupling element which is stiff in at least one predetermined direction may be arranged within the fluid-tight decoupling element. In the case of a decoupling element designed as a tubular universal joint, the arrangement within a bellows, for example, may lead to an improvement in the flow behavior. In comparison with a solution comprising only a bellows, it is for example possible to avoid the occurrence of vortex separations at the diameter discontinuity between the tube and bellows. The effects of the incisions in the tube that are used for forming the joint are typically significantly lower and can be disregarded in the case of the usually low flow velocities during the operation of the projection exposure apparatus.

The axial stiffness of the universal joint also can help prevent an elongation and hence possible damage to the bellows, as a result of which the maximum pressure in the connecting element can be increased. For example, the temperature-control performance can be increased as a result. In an alternative to the universal joint, the decoupling element which is stiff in at least one predetermined direction may also be formed as a joint rod, which may for example be held by receptacles connected to the flange of the bellows by way of connecting pieces. The decoupling elements arranged in the fluid are expediently produced from a corrosion-resistant material such as stainless steel.

In an embodiment, the decoupling element which is stiff in at least one predetermined direction may be arranged outside the fluid-tight decoupling element. The latter may be designed as a universal joint in turn, wherein the arrangement outside the fluid greatly simplifies the selection of materials that can be used for the decoupling element. This is desirable in that even very complex geometries, which are produced by an additive manufacturing method for example, may also be used.

The degree of rotational freedom about the longitudinal axis of at least one decoupling element may be designed to be stiff. A desirable feature thereof is that parasitic forces and moments that may arise cannot cause any twist, or can only cause a negligible twist, of the decoupling elements about their longitudinal axis. As a result, it is also possible to avoid a displacement of the center of stiffness, whereby it is possible to minimize parasitic forces and moments on the components by a static or dynamic change in the internal pressure.

In an embodiment, the decoupling element designed to be stiff in a predetermined direction may be designed to be retrofittable in such a way that, in addition to an already existing fluid-tight decoupling element, it can be arranged between the same sections of the connecting element.

The retrofittable decoupling element may be formed in at least two parts. For example, the at least two parts can be connected by a clamp. This is desirable in that already existing systems can be retrofitted in situ.

In an embodiment, the connecting element may comprise at least one damping element. The latter is desirable in that the dynamic transfer functions of the connecting element for example may be damped.

The damping element may be integrated into the decoupling element which is stiff in at least one predetermined direction. This is desirable because no additional installation space need be provided for securing an independent damper to the connecting element.

In an alternative, the damping element may be arranged in a damper which is independent of the decoupling elements. For example, the damping elements may be designed as a rubber damper or as an O-ring in this case, wherein the damping element is arranged between two surfaces that move relative to each other. In this case, the damper may be designed such that the damping is predominantly based on the material damping of a material used for the damping element.

The damper may also be in the form of a tuned mass damper, whereby a comparatively high damping effect can be attained, especially for a predetermined frequency.

### BRIEF DESCRIPTION OF THE DRAWINGS

Exemplary embodiments and variants of the disclosure will be explained in more detail below on the basis of the drawing, in which:

FIG. 1 schematically shows a meridional section of a projection exposure apparatus for EUV projection lithography;

FIG. 2 schematically shows a meridional section of a projection exposure apparatus for DUV projection lithography;

FIG. 3 shows a known connecting element;

FIGS. 4A and 4B show embodiments of a detail of a connecting element according to the disclosure;

FIG. 5 shows an embodiment of a detail of a connecting element according to the disclosure;

FIGS. 6A and 6B show embodiments of a detail of a connecting element according to the disclosure;

FIG. 7 shows a model of a connecting element according to the disclosure for calculating the static and dynamic transmission properties of the connecting element according to the disclosure; and

FIG. 8 shows a diagram with a comparison of the transfer function of pressure reaction loads at the connections for pressure changes in the connecting element for a connecting element known from the prior art and the connecting element according to the disclosure.

### DETAILED DESCRIPTION

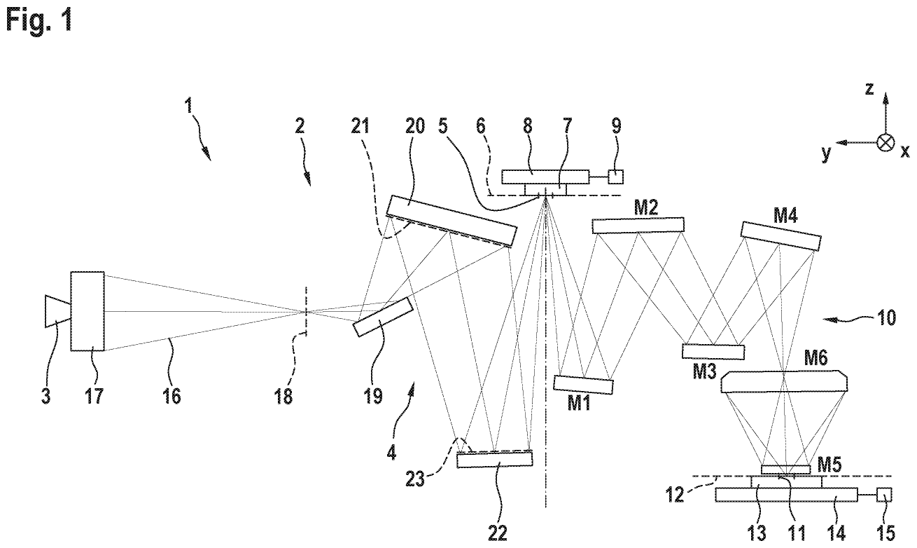

In the following text, certain constituent parts of a microlithographic projection exposure apparatus 1 are described by way of example initially with reference to FIG. 1. The description of the fundamental setup of the projection exposure apparatus 1 and the constituent parts thereof are understood here to be non-limiting.

One embodiment of an illumination system 2 of the projection exposure apparatus 1 has, in addition to a radiation source 3, an illumination optics unit 4 for illuminating an object field 5 in an object plane 6. In an alternative embodiment, the light source 3 can also be provided as a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable for example in a scanning direction by way of a reticle displacement drive 9.

A Cartesian xyz-coordinate system is depicted in FIG. 1 for explanation purposes. The x-direction runs perpendicularly to the plane of the drawing into the latter. The y-direction runs horizontally, and the z-direction runs vertically. The scanning direction runs in the y-direction in FIG. 1. The z-direction runs perpendicularly in relation to the object plane 6.

The projection exposure apparatus 1 comprises a projection optics unit 10. The projection optics unit 10 is used to image the object field 5 into an image field 11 in an image plane 12. The image plane 12 runs parallel to the object plane 6. Alternatively, an angle between the object plane 6 and the image plane 12 that differs from 0° is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable, for example in the y-direction, by way of a wafer displacement drive 15. The displacement, firstly, of the reticle 7 by way of the reticle displacement drive 9 and, secondly, of the wafer 13 by way of the wafer displacement drive 15 can be synchronized with one another.

The radiation source 3 is an EUV radiation source. The radiation source 3 emits EUV radiation 16, which is also referred to below as used radiation, illumination radiation or illumination light. The used radiation has fore example a wavelength in the range of between 5 nm and 30 nm. The radiation source 3 can be a plasma source, for example a laser-produced plasma (LPP) source or a gas discharge-produced plasma (GDPP) source. It can also be a synchrotron-based radiation source. The radiation source 3 can be a free electron laser (FEL).

The illumination radiation 16 emanating from the radiation source 3 is focused by a collector 17. The collector 17 can be a collector with one or more ellipsoidal and/or hyperboloidal reflection surfaces. The illumination radiation 16 can be incident on the at least one reflection surface of the collector 17 with grazing incidence (GI), i.e. at angles of incidence of greater than 45° relative to the direction of the normal to the mirror surface, or with normal incidence (NI), i.e. at angles of incidence of less than 45°. The collector 17 can be structured and/or coated on the one hand for optimizing its reflectivity for the used radiation and on the other hand for suppressing extraneous light.

Downstream of the collector 17, the illumination radiation 16 propagates through an intermediate focus in an intermediate focal plane 18. The intermediate focal plane 18 may represent a separation between a radiation source module, comprising the radiation source 3 and the collector 17, and the illumination optics unit 4.

The illumination optics unit 4 comprises a deflection mirror 19 and, disposed downstream thereof in the beam path, a first facet mirror 20. The deflection mirror 19 may be a planar deflection mirror or alternatively a mirror with a beam-influencing effect that goes beyond the pure deflection effect. In addition to that or in an alternative, the deflection mirror 19 may be embodied as a spectral filter that separates a used light wavelength of the illumination radiation 16 from extraneous light of a wavelength deviating therefrom. If the first facet mirror 20 is arranged in a plane of the illumination optics unit 4 that is optically conjugate to the object plane 6 as a field plane, it is also referred to as a field facet mirror. The first facet mirror 20 comprises a multiplicity of individual first facets 21, which are also referred to below as field facets. FIG. 1 illustrates only some of these facets 21 by way of example.

The first facets 21 can be in the form of macroscopic facets, for example as rectangular facets or as facets with an arcuate or partly circular edge contour. The first facets 21 can be in the form of planar facets or alternatively convexly or concavely curved facets.

As is known from DE 10 2008 009 600 A1, for example, the first facets 21 themselves may each also be composed of a multiplicity of individual mirrors, for example a multiplicity of micromirrors. The first facet mirror 20 can be in the form of a microelectromechanical system (MEMS system). For details, reference is made to DE 10 2008 009 600 A1.

The illumination radiation 16 travels horizontally, i.e. in the y-direction, between the collector 17 and the deflection mirror 19.

In the beam path of the illumination optics unit 4, a second facet mirror 22 is disposed downstream of the first facet mirror 20. If the second facet mirror 22 is arranged in a pupil plane of the illumination optics unit 4, it is also referred to as a pupil facet mirror. The second facet mirror 22 may also be arranged at a distance from a pupil plane of the illumination optics unit 4. In this case, the combination of the first facet mirror 20 and the second facet mirror 22 is also referred to as a specular reflector. Specular reflectors are known from US 2006/0132747 A1, EP 1 614 008 B1 and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which can for example have a round, rectangular or else hexagonal boundary, or may alternatively be facets composed of micromirrors. In this regard, reference is likewise made to DE 10 2008 009 600 A1.

The second facets 23 may have planar or alternatively convexly or concavely curved reflection surfaces.

The illumination optics unit 4 thus forms a doubly faceted system. This basic principle is also referred to as a fly's eye condenser (fly's eye integrator).

It may be desirable to arrange the second facet mirror 22 not exactly in a plane that is optically conjugate to a pupil plane of the projection optics unit 10. The pupil facet mirror 22 may be arranged with a tilt relative to a pupil plane of the projection optics unit 10, as described for example in DE 10 2017 220 586 A1.

The second facet mirror 22 is used to image the individual first facets 21 into the object field 5. The second facet mirror 22 is the last beam-shaping mirror or else actually the last mirror for the illuminating radiation 16 in the beam path upstream of the object field 5.

In a further embodiment (not illustrated) of the illumination optics unit 4, a transfer optics unit contributing for example to the imaging of the first facets 21 into the object field 5 may be arranged in the beam path between the second facet mirror 22 and the object field 5. The transfer optics unit may have exactly one mirror, or alternatively two or more mirrors arranged one behind another in the beam path of the illumination optics unit 4. The transfer optics unit may comprise one or two normal-incidence mirrors (NI mirrors) and/or one or two grazing-incidence mirrors (GI mirrors).

In the embodiment shown in FIG. 1, the illumination optics unit 4 has exactly three mirrors downstream of the collector 17, specifically the deflection mirror 19, the field facet mirror 20 and the pupil facet mirror 22.

In another embodiment of the illumination optics unit 4, the deflection mirror 19 may also be omitted, and so the illumination optics unit 4 can then have exactly two mirrors downstream of the collector 17, specifically the first facet mirror 20 and the second facet mirror 22.

The imaging of the first facets 21 into the object plane 6 via the second facets 23 or using the second facets 23 and a transfer optics unit is generally only approximate imaging.

The projection optics unit 10 comprises a plurality of mirrors Mi, which are consecutively numbered in accordance with their arrangement in the beam path of the projection exposure apparatus 1.

In the example illustrated in FIG. 1, the projection optics unit 10 comprises six mirrors M1 to M6. Alternatives with four, eight, ten, twelve or any other number of mirrors Mi are likewise possible. The penultimate mirror M5 and the last mirror M6 each have a through-opening for the illumination radiation 16. The projection optics unit 10 is a doubly obscured optics unit. The projection optics unit 10 has an image-side numerical aperture that is greater than 0.5 and can also be greater than 0.6 and for example can be 0.7 or 0.75.

Reflection surfaces of the mirrors Mi can be in the form of free-form surfaces without an axis of rotational symmetry. Alternatively, the reflection surfaces of the mirrors Mi may be designed as aspherical surfaces with exactly one axis of rotational symmetry of the reflection surface shape. Just like the mirrors of the illumination optics unit 4, the mirrors Mi may have highly reflective coatings for the illumination radiation 16. These coatings may be in the form of multilayer coatings, such as with alternating layers of molybdenum and silicon.

The projection optics unit 10 has a large object-image shift in the y-direction between a y-coordinate of a center of the object field 5 and a y-coordinate of the center of the image field 11. This object-image shift in the y-direction can be of approximately the same magnitude as a z-distance between the object plane 6 and the image plane 12.

The projection optics unit 10 can have an anamorphic configuration. For example, it has different imaging scales βx, βy in the x- and y-directions. The two imaging scales βx, βy of the projection optics unit 10 can be (βx, βy)=(+/−0.25, +/−0.125). A positive imaging scale β means imaging without image inversion. A negative sign for the imaging scale β means imaging with image inversion.

The projection optics unit 10 thus leads to a reduction in size with a ratio of 4:1 in the x-direction, i.e. in a direction perpendicular to the scanning direction.

The projection optics unit 10 leads to a reduction in size with a ratio of 8:1 in the y-direction, i.e. in the scanning direction.

Other imaging scales are likewise possible. Imaging scales with the same signs and the same absolute values in the x- and y-directions, for example with absolute values of 0.125 or 0.25, are also possible.

The number of intermediate image planes in the x-direction and in the y-direction in the beam path between the object field 5 and the image field 11 can be the same or can be different, depending on the embodiment of the projection optics unit 10. Examples of projection optics units with different numbers of such intermediate images in the x- and y-directions are known from US 2018/0074303 A1.

In each case, one of the pupil facets 23 is assigned to exactly one of the field facets 21 for the purpose of forming a respective illumination channel for illuminating the object field 5. For example, this may result in illumination according to the Köhler principle. The far field is decomposed into a plurality of object fields 5 with the aid of the field facets 21. The field facets 21 generate a plurality of images of the intermediate focus on the pupil facets 23 respectively assigned thereto.

The field facets 21 are each imaged by an assigned pupil facet 23 onto the reticle 7 in a manner overlaid on one another in order to illuminate the object field 5. The illumination of the object field 5 is for example as homogeneous as is reasonably possible. It can have a uniformity error of less than 2%. Field uniformity may be achieved by overlaying different illumination channels.

The illumination of the entrance pupil of the projection optics unit 10 can be defined geometrically by way of an arrangement of the pupil facets. The intensity distribution in the entrance pupil of the projection optics unit 10 may be set by selecting the illumination channels, such as the subset of the pupil facets that guide light. This intensity distribution is also referred to as illumination setting.

A likewise preferred pupil uniformity in the region of portions of an illumination pupil of the illumination optics unit 4 that are illuminated in a defined manner may be achieved by a redistribution of the illumination channels.

Further aspects and details of the illumination of the object field 5 and for example of the entrance pupil of the projection optics unit 10 are described below.

The projection optics unit 10 may have a homocentric entrance pupil. The latter can be accessible. It can also be inaccessible.

The entrance pupil of the projection optics unit 10 cannot, as a rule, be exactly illuminated using the pupil facet mirror 22. The aperture rays often do not intersect at a single point in the event of imaging by the projection optics unit 10 that telecentrically images the center of the pupil facet mirror 22 onto the wafer 13. However, it is possible to find an area in which the spacing of the aperture rays, determined in pairs, is minimal. This area is the entrance pupil or an area conjugate thereto in real space. For example, this area exhibits a finite curvature.

It may be the case that the projection optics unit 10 has different poses of the entrance pupil for the tangential beam path and for the sagittal beam path. In this case, an imaging element, such as an optical component of the transfer optics unit, should be provided between the second facet mirror 22 and the reticle 7. With the aid of this optical element, the different poses of the tangential entrance pupil and the sagittal entrance pupil can be taken into account.

In the arrangement of the components of the illumination optics unit 4 illustrated in FIG. 1, the pupil facet mirror 22 is arranged in an area conjugate to the entrance pupil of the projection optics unit 10. The field facet mirror 20 is arranged so as to be tilted with respect to the object plane 6. The first facet mirror 20 is arranged so as to be tilted with respect to an arrangement plane defined by the deflection mirror 19.

The first facet mirror 20 is arranged so as to be tilted with respect to an arrangement plane defined by the second facet mirror 22.

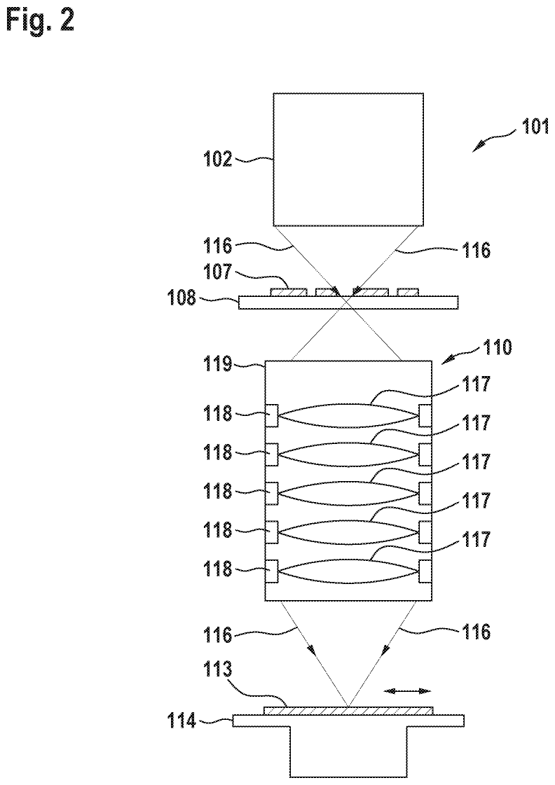

FIG. 2 schematically shows a meridional section through a further projection exposure apparatus 101 for DUV projection lithography, in which the disclosure can likewise be used.

The setup of the projection exposure apparatus 101 and the principle of the imaging are comparable with the setup and procedure described in FIG. 1. Identical component parts are denoted by a reference sign increased by 100 relative to FIG. 1, i.e. the reference signs in FIG. 2 begin with 101.

By contrast to an EUV projection exposure apparatus 1 as described in FIG. 1, refractive, diffractive and/or reflective optical elements 117, such as lens elements, mirrors, prisms, terminating plates, and the like, can be used for imaging or for illumination in the DUV projection exposure apparatus 101 on account of the greater wavelength of the DUV radiation 116, employed as used light, in the range of 100 nm to 300 nm, for example in the region of 193 nm. The projection exposure apparatus 101 in this case comprises an illumination system 102, a reticle holder 108 for receiving and exactly positioning a reticle 107, which is provided with a structure and is used to determine the later structures on a wafer 113, a wafer holder 114 for holding, moving, and exactly positioning this very wafer 113, and a projection lens 110, with a plurality of optical elements 117 held by way of mounts 118 in a lens housing 119 of the projection lens 110.

The illumination system 102 provides DUV radiation 116 for the imaging of the reticle 107 on the wafer 113. A laser, a plasma source or the like can be used as the source of this radiation 116. The radiation 116 is shaped in the illumination system 102 via optical elements such that the DUV radiation 116 has the desired properties in terms of diameter, polarization, shape of the wavefront and the like when it is incident on the reticle 107.

Apart from the additional use of refractive optical elements 117, such as lens elements, prisms, terminating plates, the setup of the downstream projection optics unit 101 with the lens housing 119 does not differ in principle from the setup described in FIG. 1 and is therefore not described in further detail.

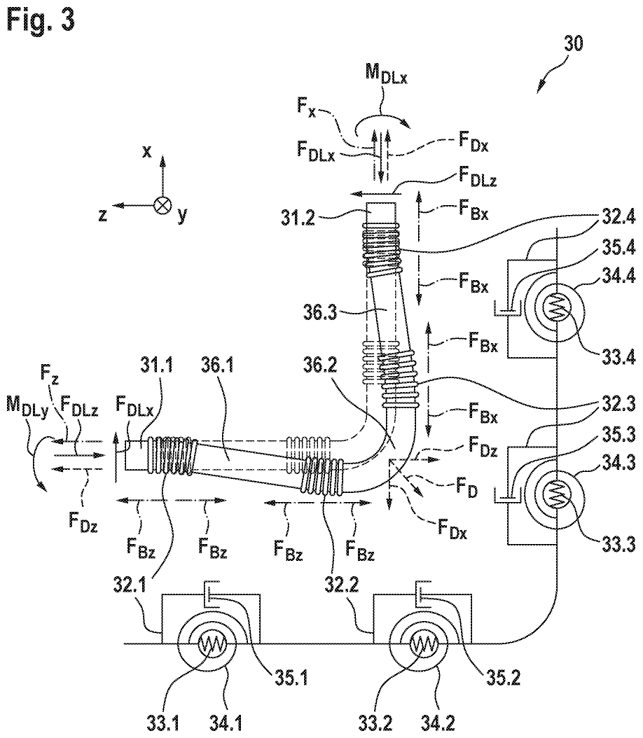

FIG. 3 shows a fluid-conducting connecting element 30 known from the prior art. It comprises two connections 31.1, 31.2 which are connected to two components (not shown here) by way of corresponding interfaces. For example, the components could be components in a projection exposure apparatus 1 as described in FIG. 1, for example a mirror M3, through which fluid flows for temperature-control purposes, and a load-bearing structure, which is not depicted in FIG. 1. The connecting element 30 serves to supply and remove the temperature-control fluid to and from the mirror M3, with the connecting element also being connected to the load-bearing structure.

The connecting element 30 furthermore comprises decoupling elements in the form of bellows 32.1, 32.2, 32.3, 32.4, which reduce or even completely prevent a transmission of static and/or dynamic mechanical disturbances from the load-bearing structure to the mirror M3. In the embodiment illustrated in FIG. 3, two bellows 32.1, 32.4 are arranged, respectively, between the connections 31.1, 31.2 and a first section 36.1 and a third section 36.3 of the connecting element 30, with the two sections 36.1, 36.3 being in the form of straight tubes. Furthermore, two bellows 32.2, 32.3 are arranged, respectively, between the first 36.1 and third sections 36.3 and a second section 36.2 arranged therebetween and formed in an arcuate shape.

In FIG. 3, the connecting element 30 is depicted using dashed lines for an applied differential pressure p between the interior and exterior of the connecting element 30 of zero bar and depicted using solid lines for a differential pressure p of one bar. A resultant force F_{D} arises on the outer side of the second section formed as a quarter arc 36.2 owing to the areas of different sizes at the inner radius and outer radius, on which the differential pressure p acts. It is quite evident that on account of the force F_{D}, the quarter arc 36.2 migrates out of its original position in the xz-plane in the plane of the drawing owing to the bellows 31.1, 31.2, 31.3, 31.4 being comparatively soft axially and angularly.

For a more detailed explanation of the cause of the so-called pressure reaction loads F_{DL}, M_{DL} caused thereby at the connections 31.1, 31.2, the connecting element 30 is additionally represented by an equivalent model, which is used as a basis for static and dynamic calculations of the pressure reaction loads F_{DL}, M_{DL}. The sections 36.1, 36.2, 36.3 are represented as simple lines, whereas the bellows 32.1, 32.2, 32.3, 32.4 are each represented by an axial spring 33.x, a torsion spring 34.x and a damping member 35.x. The springs 33.x have an axial stiffness kₐₓᵢₐₗ, the rotation springs 34.x have an angular stiffness k_{ang}, and the damping member has a damping d.

If a differential pressure p is applied to the connecting element 30, a force F_{D} acts at the vertex of the quarter arc 36.2, as described further above; the force can be decomposed into two forces F_{Dz}, F_{Dx} in the respective portions 36.1, 36.3 aligned parallel to the x-axis and z-axis.

In FIG. 3, the forces F_{D}, F_{Dz}, F_{Dx} are depicted as dashed arrows, with F_{D} being calculated as follows:

$${F}_{D} = \frac{π}{4} {d}_{i}^{2} * p$$

where dᵢ=connecting element internal diameter.

Furthermore, a force F_{B}—represented by dash-dotted arrows in FIG. 3—acts on the bellows owing to the differential pressure p, as follows:

$${F}_{B} = \frac{π}{4} ( {d}_{m}^{2} - {d}_{i}^{2} ) * p$$

where:
dₘ=bellows mean diameter
p=differential pressure, corresponding to the differential pressure between the surroundings and within the connecting element

Pressure reaction loads in the form of forces F_{DL} and moments M_{DL}—represented by dashed arrows in FIG. 3—are caused at the connections 31.1, 31.2 by the two forces F_{D}, F_{B}. The pressure reaction loads F_{DL}, M_{DL} can be described as a function of the forces F_{D}, F_{B} and the ratio of the angular stiffness to the axial stiffness k_{ang}/kₐₓᵢₐₗ Of the bellows 32.1, 32.2, 32.3, 32.4. In this case, the smaller the ratio k_{ang}/kₐₓᵢₐₗ, the lower the pressure reaction loads F_{DL}, M_{DL}.

$${F}_{DL} , {M}_{D L} = f ( \frac{{k}_{ang}}{{k}_{a x}} , {F}_{D} , {F}_{B} )$$

The forces F_{DLz}, F_{DLx}, F_{Dz}, F_{Bx}, F_{Bz} represented in FIG. 3 and the moment M_{DLy} are based on so-called open modeling. This means that the connecting element 30 is open at its ends, i.e. not closed by a cover, for example. This leads to both the forces F_{Dx}, F_{Dz} acting in the system owing to the differential pressure p at the quarter arc 36.2 and their reaction forces F_{Dx}, F_{Dz}, which are equal in magnitude, being represented at the open ends of the connecting element. This is desirable ageous in that this renders the forces F_{D} leading to the deflection of the connecting element 30 becoming visible; this would not be the case for a closed system with a cover since the forces already cancel each other out within the system in that case and are therefore not visible at the mounts of the connections 31.1, 31.2. Thus, a closed system only considers the forces that are measurable at the connections 31.1, 31.2, without considering the forces F_{D} acting within the system. The same applies to the bellows forces F_{B}, which also act at the respective connections to the sections 36.1, 36.2, 36.3, i.e. act within the system and therefore cannot be seen in a closed system. The pressure reaction loads F_{DL}, M_{DL} are the reaction loads caused at the fixedly clamped connections 31.1, 31.2 of the restoring forces of the bellows 36.1, 36.2, 36.3, 36.4 which are caused by the deflection of the connecting element 30.

As a result of the symmetrical structure of the connecting element 30, the pressure reaction loads F_{DL}, M_{DL} plotted in FIG. 3 cancel each other out at the connections 31.1, 31.2, and so the connecting element 30 is in equilibrium.

A bearing force F_{z}—represented by a dash-dot-dotted line—arising from the difference between the open-end compressive force F_{Dz} and the pressure reaction load F_{DLz} acts on the connection 36.1 depicted bottom left in FIG. 3 when calculations are performed for such an open system. The bearing force Fₓ corresponds to the pressure reaction force F_{DLx}. In the symmetrical embodiment shown, the bearing force F_{y} is equal to zero.

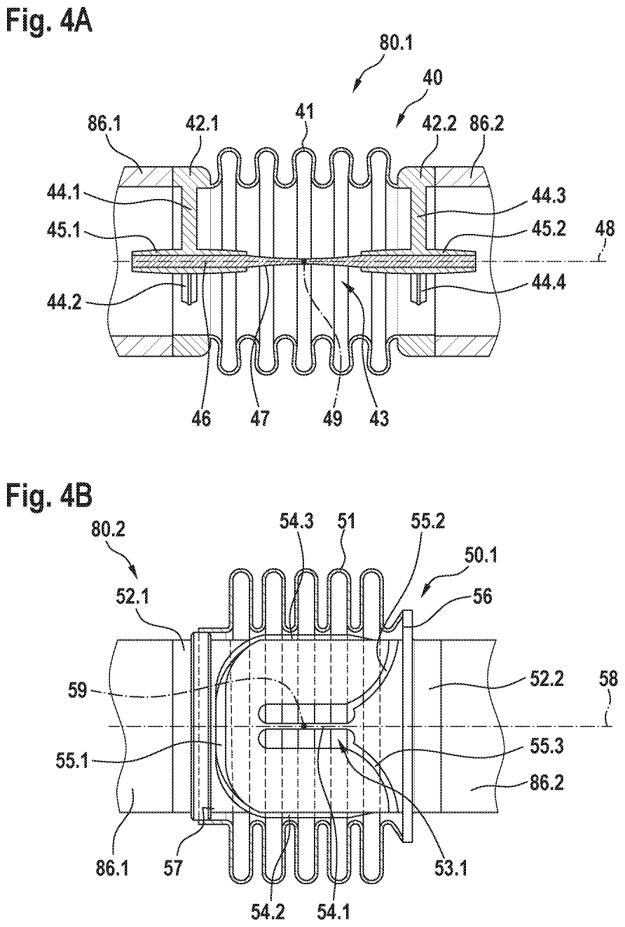

The two limbs are lengthened on account of the bellows 36.x being relatively soft in the axial direction, with the elongation predominantly being caused by the bellows 36.x in the limbs, whereby the second section 36.2 yields as illustrated in FIG. 3. In addition to an elongation, this yielding movement also leads to the bellows 36.1, 36.2, 36.3, 36.4 tilting, whereby axial and lateral forces F_{Bz}, F_{Bx} are caused and contribute at the connections 31.1 to the pressure reaction loads in the form of an axial force F_{DLz}, in the form of a lateral force F_{DLx} and in the form of a moment M_{DLy}. FIG. 4A shows a first embodiment of a decoupling module 40 having a first decoupling element in the form of a bellows 41 and a second decoupling element in the form of a rod decoupling mechanism 43, as may be used in a connecting element 80.1 according to the disclosure. The two decoupling elements 41, 43 thus connect the same sections 86.1, 86.2 to each other.

The bellows 41 corresponds to a bellows 32.x (FIG. 3) known from the prior art and comprises a flange 42.1, 42.2 on both sides for attachment to the sections 86.1, 86.2 of the connecting element 80.1. The sections 86.1, 86.2 correspond to the sections 36.1, 36.2 (FIG. 3).

Three connecting pieces are arranged on the inner surfaces of each flange 42.1, 42.2 and each hold a receptacle 45.1, 45.2, but only the connecting pieces 44.1 and 44.2 as well as 44.3 and 44.4 are visible owing to the sectional illustration. The receptacles 45.1, 45.2 accommodate an articulated rod 46, which has a taper 47 at its center. The taper 47 is designed such that the axial stiffness is maximal for a predetermined angular stiffness. Given a suitable design, the axial stiffness can be increased by a factor in the range of 40 to 60 vis-à-vis a decoupling module 32.x designed merely as a bellows (FIG. 3) without causing a significant increase (factor 0.5 to 2) in the angular stiffness. The rod decoupling mechanism 43 thus acts for the bellows 41 in a manner comparable to a tie rod, and so the elongation of the bellows 41 under pressure is avoided. In the case of a second section formed as a quarter arc 86.2 (see FIG. 3), this leads to a smaller movement of the second section 86.2 in the yz-plane, whereby the angular deflection of the decoupling modules 40 is also reduced, whereby in turn the pressure reaction loads F_{DL}, M_{DL} at the connections 31.1, 31.2 (FIG. 3) are reduced.

The effect of the rod decoupling mechanism 43 as a tie rod moreover allows a higher pressure to be applied to the connecting element 80.1. This is possible because the elongation of the bellows 41 which limits the maximum possible pressure and the plastic deformation of the bellows possibly occurring as a result are minimized or completely avoided as a result of the tie rod.

The bellows 41 in turn has a high torsional stiffness, and so the two decoupling elements 41, 43 complement each other in terms of the effective directions of their stiffnesses.

The material of the rod decoupling mechanism 43 may be chosen such that this does not result in any chemical interactions, for example corrosion, with the fluid. For example, stainless steel lends itself as the material for the rod decoupling mechanism 43 in the case of high-purity water usually used as a fluid.

In the embodiment illustrated in FIG. 4A, the bellows 41 and the rod decoupling mechanism 43 are arranged coaxially about a common axis 48 and have the same pivot point 49. As a result, parasitic forces in the event of the bellows 41 and the rod decoupling mechanism 43 tilting are reduced or even completely avoided.

The higher axial stiffness has the effect that the natural frequencies of the connecting element 80.1 are shifted to higher frequencies, as yet to be explained in detail on the basis of FIG. 8. For example, the higher natural frequencies lead to a greatly reduced influence of the pressure reaction loads F_{DLz}, F_{DLx} and moments M_{DLy} on a position control for the mirror M3.

FIG. 4B shows a further embodiment of a decoupling module 50.1 having a first decoupling element in the form of a bellows 51 and a second decoupling element in the form of a universal joint 53.1, as may be used in a connecting element 80.2 according to the disclosure, wherein, where appropriate, mutually corresponding elements are denoted by reference signs increased by 10 vis-à-vis FIG. 4A. The two decoupling elements 51, 53.1 thus connect the same sections 86.1, 86.2 to each other. In FIG. 4B, the bellows 51 are illustrated in section such that the internal universal joint 53.1 can be identified. The latter comprises a first joint formed by a pair of leaf springs 54.1 extending in parallel with the common axis of the decoupling elements 51, 53.1, wherein, in the illustration in FIG. 4B, the second leaf spring, which is positioned behind the plane of the drawing, is covered by the leaf spring 54.1. Furthermore, the universal joint 53.1 comprises a second joint formed by a second pair of leaf springs 54.2, 54.3, which are arranged offset by 90° with respect to the first pair 54.1. In the embodiment illustrated in FIG. 4B, the leaf springs 54.1, 54.2, 54.3 are produced monolithically, i.e. formed from a piece of tube by corresponding cutouts 55.1, 55.2, 55.3.

The two joints enable decoupling about each axis perpendicular to the common axially aligned axis 58.

The pivot point 59 of the two joints is identical to the pivot point of the bellows 51, and so parasitic forces and/or moments are not introduced into the connections 32.1, 32.2 (FIG. 3).

The axial stiffness achieved by the universal joint 53.1 is comparable to that of the rod decoupling mechanism 43 described in FIG. 4A. The angular stiffnesses are likewise in a comparable order of magnitude.

The universal joint 53.1 comprises a stop 56 and a connecting surface 57 for securing the bellows 51 to the universal joint 53.1. The bellows 51 is pushed onto the universal joint 53.1 as far as the stop 56 and is connected to the latter in fluid-tight fashion on the connecting surface 57, for example by laser welding. In an alternative to the integral bond, the connection may also be established using form-fitting or force-fitting connection technology.

As a result of the arrangement in the interior of the bellows 51, the universal joint 53.1 becomes part of the fluid-conducting connecting element 80, i.e. fluid flows therethrough. This is desirable in that the vortex separations that usually occur in the bellows 51 (without a universal joint 53.1) above a certain flow rate can be at least reduced or even completely avoided at the same and higher flow rates. As a result, both higher pressures and higher flow rates can be realized in addition as a result of the axial stiffening acting as a tie rod for the bellows 41, 51, described above, and the universal joint 53.1 with a fluid flowing therethrough.

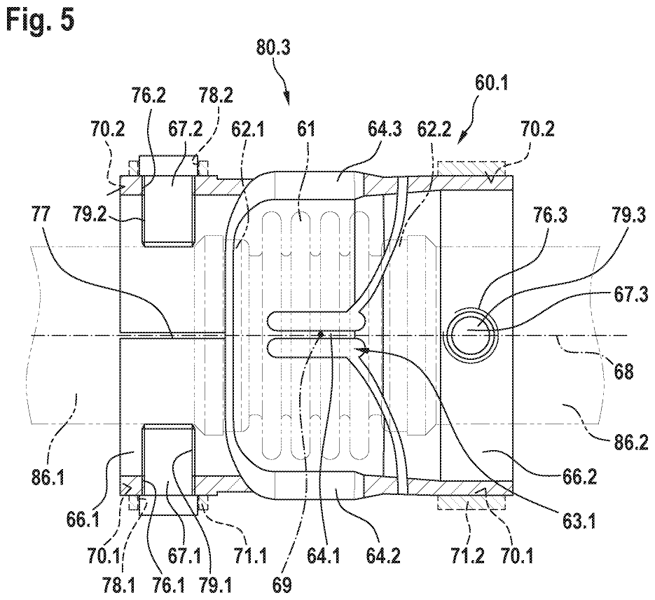

FIG. 5 shows a further embodiment of a decoupling module 60.1 having a first decoupling element in the form of a bellows 61 and a second decoupling element in the form of a universal joint 63.1, as may be used in a connecting element 80.3 according to the disclosure, wherein, where appropriate, mutually corresponding elements are denoted by reference signs increased by 10 vis-à-vis FIG. 4B. Once again, the two decoupling elements 61, 63.1 connect the sections 86.1, 86.2 to each other. The bellows 61 is represented in transparent fashion in FIG. 5 such that, in the embodiment shown, the exterior universal joint 63.1, depicted in section, can be identified. The universal joint 63.1 is designed in functionally identical fashion to the universal joint 53.1 depicted in FIG. 4B.

Like in the embodiment depicted in FIG. 4B, the bellows 61 is welded to the sections 86.1, 86.2 of the connecting element 80.3.

The connection of the universal joint 63.1 to the sections 86.1, 86.2 is designed such that through-holes 67.1, 67.2, 67.3 with threads 76.1, 76.2, 76.3 are formed in the universal joint 63.1. Furthermore, slots 77 are formed in the universal joint 63.1 so as to be tilted through 90° with respect to the through-holes 67.1, 67.2, 67.3. The universal joint 63.1 is clamped by screws 79.1, 79.2, 79.3 to the sections 86.1, 86.2 in the region next to the flanges 62.1, 62.2 of the bellows 61.

In an alternative, the universal joint 63.1 may also be screwed to the sections 86.1, 86.2. In this case, threads are formed in the sections 86.1, 86.2.

In a further embodiment, the universal joint 63.1 may be formed in two parts, for example in the form of two half shells. The cut faces of the sectional illustration shown in FIG. 5 in this case correspond to joining surfaces 70.1, 70.2 of one of two half shells, with FIG. 5 depicting only the rear half shell which projects into the plane of the drawing. The half shells are connected to each other at the joining surfaces 70.1, 70.2. After the two half shells have been aligned with each other, they are connected by clamps 71.1, 71.2. This is desirable in that the universal joint 63.1 can easily be retrofitted into an already existing connecting element 30 (FIG. 3) from the prior art, i.e. without disassembly or replacement of elements in the connecting element 30. As a result of through-holes 78.1, 78.2, 78.3 formed in the clamps 71.1, 71.2, clamping would work identically to the method described further above.

Arranging the universal joint 63.1 outside the fluid is desirable in that a greater selection of materials is available, since there are no increased demands in relation to corrosion resistance.

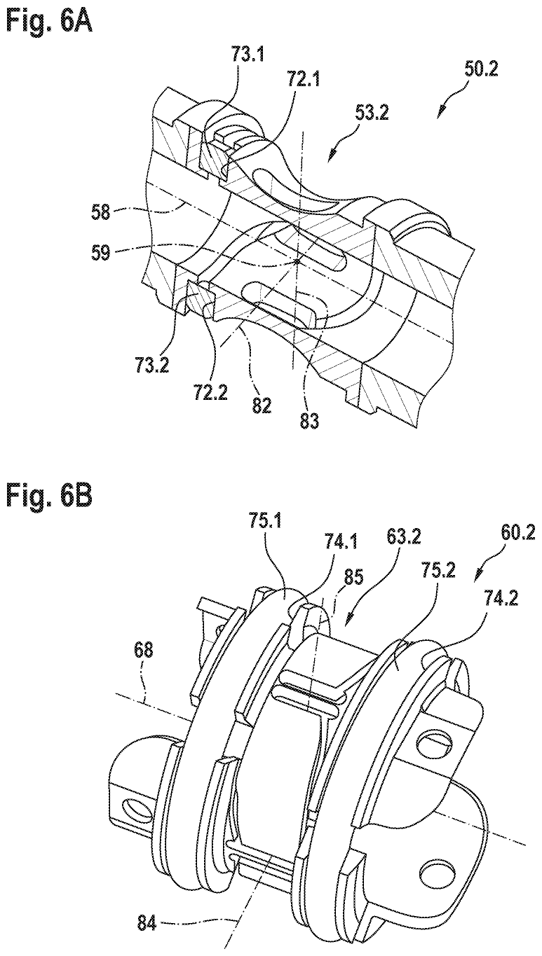

Augmenting the first axially soft bellows 41, 51, 61 with an axially stiff and angularly soft second decoupling element 43, 53.1, 63.1 with a defined pivot point leads to the bellows 41, 51, 61 contributing the fluid tightness. Thus, where possible, the bellows may optionally also be replaced by a tube or a sleeve made of an elastomer or any other material with a high material damping. This is desirable in that the natural frequencies can also be attenuated, in addition to the shift to higher frequencies. In an alternative, the damping may also be in the form of an independent component of the connecting element 80.1, 80.2, 80.3 or be integrated into the universal joints 53.1, 63.1, as explained in detail in FIGS. 6A and 6B.

FIG. 6A shows a decoupling element, embodied as a universal joint 53.2, of a decoupling module 50.2 in a sectional illustration, the design of which is predominantly identical to the universal joint 53.1 illustrated in FIG. 4B, which is why reference signs were omitted for identical elements in FIG. 6A where appropriate.

Furthermore, the universal joint 53.2 comprises receiving regions 72.1, 72.2 for receiving damping elements in the form of rubber dampers 73.1, 73.2, which damp movements of the universal joint 53.2. The damping elements 73.1, 73.2 shown in FIG. 6A damp an angular movement about the axis of rotation 82 aligned perpendicular to the joint axially aligned axis 58 and a linear movement in the direction of the axis 83 aligned perpendicular to the axes 58, 82. Two further damping elements for damping an angular movement about the axes 83 and in the direction of the linear axis 82 are not illustrated or not visible owing to the sectional illustration. For example, the damping elements 73.1, 73.2 are produced from fluoro-rubber or any other elastomer and have a comparatively high material damping, whereby dynamic movements for example are damped.

FIG. 6B shows a decoupling element, embodied as a universal joint 63.2, of a decoupling module 60.2 in a sectional illustration, the design of which is predominantly identical to the universal joint 63.1 illustrated in FIG. 5, which is why reference signs were omitted for identical elements in FIG. 6B where appropriate.

Furthermore, the universal joint 63.2 comprises receiving regions 74.1, 74.2 for receiving damping elements in the form of O-rings 75.1, 75.2, which damp a movement of the universal joint 53.2. The O-ring 75.1 shown in FIG. 6B damps an angular movement about the axis 84 and a linear movement along the axis 85 perpendicular thereto. By contrast, the O-ring 75.2 damps an angular movement about the axis 85 and a linear movement along the axis 84. For example, the O-rings 75.1, 75.2 are produced from an elastomer, for example fluoro-rubber or any other suitable material, and have a comparatively high material damping, whereby dynamic movements for example are damped.

The damping elements shown in FIGS. 6A and 6B may alternatively also be arranged in independent dampers with their own kinematics, which damp the movements of the sections 86.1, 86.2, 86.3 of the connecting element 80.1, 80.2, 80.3 relative to each other independently of the decoupling element used. This also allows damping of a connecting element 80.1 having a second decoupling element in the form of a rod decoupling mechanism 43.

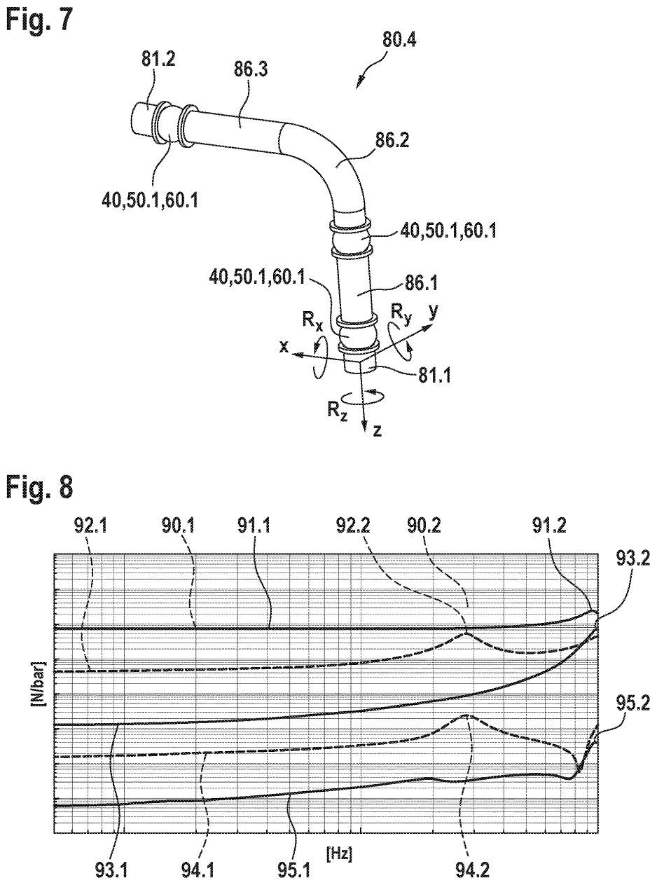

FIG. 7 shows a model of a connecting element 80.4 for calculating the effect of a higher axial stiffness, as is formed in the decoupling modules 40, 50.1, 60.1 in FIGS. 4A, 4B, 5, on the transmission behavior of the differential pressure p to the pressure reaction loads F_{DLx}, F_{DLy}, F_{DLz}. The model represents the connecting element 80.4 with the sections 86.1, 86.2, 86.3, wherein, in comparison with FIG. 3, there is no decoupling element between the third section 86.1 and the second section 86.2 in the model. The transfer functions of the ratio of the bearing forces Fₓ, F_{y}, F_{z} to the differential pressure p over frequency depicted in FIG. 8 correspond to the three axes of the coordinate system depicted in FIG. 7 at the connection 81.1. The bearing forces Fₓ, F_{y}, F_{z} are calculated using the open system explained in FIG. 3, and so the bearing forces Fₓ, F_{y} correspond to the two pressure reaction loads F_{DLx}, F_{DLy}, and F_{z} of the bearing reaction of the connection 81.1, which comprises both the force F_{D} caused by the differential pressure and the pressure reaction load F_{DLz}. The moments likewise drawn in are not illustrated in FIG. 8.

FIG. 8 shows a diagram of the three transfer forces of the ratio of the three bearing forces Fₓ, F_{y}, F_{z} to the differential pressure p over frequency, wherein the diagrams represent a qualitative statement about the change as a result of increasing the axial stiffness in the decoupling module 40, 50.1, 60.1. The ordinate of the diagram plots the ratio of bearing forces Fₓ, F_{y}, F_{z} to differential pressure p in N/bar, and the abscissa plots the frequency in Hz, with the axes having a logarithmic representation.

The curves in dashed lines correspond in each case to the transfer functions in the prior art, with a decoupling module 32.x with a comparatively low axial stiffness. The solid curves correspond in each case to the transfer functions with a decoupling module 40, 50.1, 60.1 with an axial stiffness that has been increased by a factor in the range from 40 to 60 in comparison with the prior art.

The diagram in each case shows three curve pairs 90.1, 91.1, 92.1, 93.1, 94.1, 95.1, with the even reference signs corresponding to the transfer functions on the basis of the axially soft connecting elements 30 and the odd reference signs being assigned to the axially stiff connecting elements 80.1, 80.2, 80.3, and these each correspond to a direction x, y, z.

The uppermost curve pair 90.1, 91.1 in FIG. 8 shows the transfer function of the bearing force F_{z} caused in the axial direction. The curves 90.1, 91.2 run virtually in parallel and virtually with the same value up to the first resonance 90.2. The deviation of the bearing force F_{z} of the connection 81.1 from the force F_{Dz} caused by the pressure in the xz-plane deviates by the absolute value of the pressure reaction load F_{DLx} (=bearing force Fₓ) as a result of the quarter arc 86.1 yielding. Since this is significantly lower in terms of absolute value than the force acting in the z-direction, the difference in the logarithmic representation is minimal. The increase in the first natural frequency is clearly evident from the distance between the first resonance 90.2 of the first curve 90.1 and the first resonance 91.2 of the second curve 91.1.

The second pair of curves 92.1, 93.1 shows the bearing force Fₓ. The clear decrease in the bearing force Fₓ for the axially stiff connecting element 40, 50.1, 60.1 is clearly evident from the spacing between the curves 92.1, 93.2 over the entire frequency range. Like in the case of the curve pair 90.1, 91.1, the increase in the first resonance 92.2, 93.2 for the axially stiff connecting element 40, 50.1, 60.1 is also clearly evident for this curve pair 92.1, 93.1.

The third pair of curves 94.1, 96.1 shows the bearing force F_{y}. Here, too, a clear decrease in the corresponding pressure reaction load F_{DLy} for the axially stiff connecting element 40, 50.1, 60.1 is clearly evident as a result of the spacing between the curves 94.1, 94.2 over the entire frequency range, with the absolute values being very small. Like in the case of the curve pairs 90.1, 91.1, 92.1, 93,1, the increase in the first resonance 94.2, 95.2 for the axially stiff connecting element 40, 50.1, 60.1 is also clearly evident for this curve pair 92.1, 93.1.

### LIST OF REFERENCE SIGNS

1 Projection exposure apparatus
2 Illumination system
3 Radiation source
4 Illumination optics unit
5 Object field
6 Object plane
7 Reticle
8 Reticle holder
9 Reticle displacement drive
10 Projection optics unit
11 Image field
12 Image plane
13 Wafer
14 Wafer holder
15 Wafer displacement drive
16 EUV radiation
17 Collector
18 Intermediate focal plane
19 Deflection mirror
20 Facet mirror
21 Facets
22 Facet mirror
23 Facets
30 Connecting element
31.1, 31.2 Connection component
32.1-32.4 Decoupling element
33.1-33.4 Spring
34.1-34.4 Torsion spring
35.1-35.4 Damper
36.1-36.3 Connecting element section
40 Bellows element
41 Bellows
42.1, 42.2 Flange
43 Rod decoupling mechanism
44.1-44.4 Connecting piece
45.1, 45.2 Receptacle
46 Articulated rod
47 Taper
48 Axial axis
49 Pivot point
50 Decoupling element
51 Bellows
52.1, 52.2 Flange
53.1-53.3 Universal joint
54.1-54.2 Leaf spring
55.1-55.3 Cutout
56 Stop
57 Connecting surface
58 Axial axis
59 Pivot point
60 Decoupling element
61 Bellows
62.1, 62.2 Flange
63 Universal joint
64.1-64.3 Leaf spring
65.1-65.3 Cutout
66.1, 66.2 Connecting flange
67.1-67.3 Through-hole
68 Axial axis
69 Pivot point
70.1, 70.2 Joining surface (two-part embodiment)
71.1, 71.2 Clamp
72 Receptacle for dampers
73 Rubber damper
74 Receptacle for dampers
75 O-ring
76.1-76.3 Thread
77 Slot
78.1, 78.2 Through-hole in the clamp
79 Screw
80.1-80.4 Connecting element
81.1, 81.2 Connection component
86.1-86.3 Connecting element section
87 Screws
90.1, 90.2 Transfer function/resonance N/bar x prior art
91.1, 91.2 Transfer function/resonance N/bar x novel
92.1, 92.2 Transfer function/resonance N/bar y prior art
93.1, 93.2 Transfer function/resonance N/bar y novel
94.1, 94.2 Transfer function/resonance N/bar z prior art
95.1, 95.2 Transfer function/resonance N/bar z novel
101 Projection exposure apparatus
102 Illumination system
107 Reticle
108 Reticle holder
110 Projection optics unit
113 Wafer
114 Wafer holder
116 DUV radiation
117 Optical element
118 Mounts
119 Lens housing
M1-M6 Mirror
F_{x,y,z} Bearing forces in an open system
F_{Dx,z} Force due to pressure in the connecting element
F_{Bx,Z} Force on the bellows
F_{DLx,y,z} Force of pressure reaction load on the connection flange
M_{DLx,y,z} Moment of pressure reaction load on the connection flange

What is claimed is:

1. An apparatus, comprising:
a fluid-conducting connecting element configured to connect two components of the apparatus,
wherein:
the fluid-conducting connecting element comprises a first mechanical decoupling element and a second decoupling element;
the fluid-conducting connecting element comprises first and second sections;
the first mechanical decoupling element decouples the first and second sections of the fluid-conducting connecting element from each other;
the second decoupling element decouples the first and second sections of the fluid-conducting connecting element from each other; and
the apparatus is a projection exposure apparatus.

2. The apparatus of claim 1, wherein:
the first mechanical decoupling element comprises a bellows; and
the second decoupling element comprises a joint that is stiff in a predetermined direction.

3. The apparatus of claim 2, wherein the predetermined direction is an axial direction of the second decoupling element.

4. The apparatus of claim 3, wherein the second decoupling element decouples rotation about all directions perpendicular to the predetermined direction.

5. The apparatus of claim 2, wherein the second decoupling element decouples rotation about all directions perpendicular to the predetermined direction.

6. The apparatus of claim 1, wherein the first mechanical decoupling element and the second decoupling element are coaxial.

7. The apparatus of claim 1, wherein the first mechanical decoupling element and the second decoupling element have a common center of stiffness.

8. The apparatus of claim 1, wherein the first mechanical decoupling element is fluid-tight.

9. The apparatus of claim 8, wherein the second decoupling element is stiff in a predetermined direction, and the second decoupling element is within the first mechanical decoupling element.

10. The apparatus of claim 9, wherein:
the first mechanical decoupling element comprises a bellows; and
the second decoupling element comprises a joint.

11. The apparatus of claim 8, wherein the second decoupling element is stiff in a predetermined direction, and the second decoupling element is outside the first mechanical decoupling element.

12. The apparatus of claim 11, wherein:
the first mechanical decoupling element comprises a bellows; and
the second decoupling element comprises a joint.

13. The apparatus of claim 1, wherein, for a decoupling element selected from the group consisting of the first mechanical decoupling element and the second decoupling element, a degree of rotational freedom about a longitudinal axis of the decoupling element is stiff.

14. The apparatus of claim 1, wherein:
the first mechanical decoupling element comprises a bellows; and
the second decoupling element comprises a joint that is stiff in a predetermined direction;
the second decoupling element is within the first mechanical decoupling element; and
the second decoupling element is retrofittable so that it is arrangeable between the first and second sections of the first mechanical connecting element.

15. The apparatus of claim 14, wherein the second decoupling element comprises two parts.

16. The apparatus of claim 1, wherein the fluid-conducting connecting element comprises a damping element.

17. The apparatus of claim 16, wherein the damping element is integrated into the second decoupling element, and the second decoupling element is stiff in a predetermined direction.

18. The apparatus of claim 16, further comprising a damper which is independent of the first mechanical decoupling element and the second decoupling element, wherein the damping element is in the damper.

19. The apparatus of claim 1, wherein the apparatus is a semiconductor lithography projection exposure apparatus.

20. The apparatus of claim 1, further comprising the two components.
